(19) United States
(12) Patent Application Publication
(10) Pub. No.: US 2026/0112396 A1
(43) Pub. Date: Apr. 23, 2026

(54) SEMICONDUCTOR DEVICE AND ELECTRONIC SYSTEM INCLUDING THE SAME

(71) Applicant: Samsung Electronics Co., Ltd., Suwon-si (KR)

(72) Inventors: KIBONG MOON, Suwon-si (KR); DAJIN KIM, Suwon-si (KR); SEUNGSOB KIM, Suwon-si (KR); SANG-YONG PARK, Suwon-si (KR); SEUNG JAE BAIK, Suwon-si (KR); GUN-WOOK YOON, Suwon-si (KR); NAYEONG YUN, Suwon-si (KR); SUNG-BOK LEE, Suwon-si (KR); JAEDUK LEE, Suwon-si (KR)

(21) Appl. No.: 19/329,666

(22) Filed: Sep. 16, 2025

(30) Foreign Application Priority Data
Oct. 21, 2024 (KR) 10-2024-0144301

(51) Int. Cl. G11C 5/06; H01L 23/00; H01L 25/18; H10B 41/10; H10B 41/27; H10B 41/35; H10B 41/41; H10B 41/42; H10B 43/10; H10B 43/27; H10B 43/35; H10B 43/40; H10B 80/00; H10D 80/30

(52) U.S. Cl. CPC G11C 5/063; H10B 41/10; H10B 41/27; H10B 41/35; H10B 41/41; H10B 41/42; H10B 43/10; H10B 43/27; H10B 43/35; H10B 43/40; H10B 80/00; H10D 80/30; H10W 90/00; H10W 90/20; H10W 90/24; H10W 90/732; H10W 90/734; H10W 90/752; H10W 90/754

(57) ABSTRACT

A semiconductor device includes a substrate, a stack structure including dielectric patterns and conductive patterns vertically and alternately stacked on the substrate, a source conductive pattern on the stack structure, an upper conductive line between the stack structure and the source conductive pattern, and vertical structures that penetrate the stack structure and the upper conductive line and are electrically connected to the source conductive pattern. A vertical thickness of the upper conductive line is greater than a vertical thickness of each of the conductive patterns. The vertical structure comprises a lower portion that penetrates the stack structure and an upper portion that is connected to the lower portion and penetrates the upper conductive line. A minimum horizontal width of the upper portion is greater than a minimum horizontal width of the lower portion.

### CROSS-REFERENCE TO RELATED APPLICATION

This application claims priority under 35 U.S.C § 119 to Korean Patent Application No. 10-2024-0144301 filed on Oct. 21, 2024 in the Korean Intellectual Property Office, the disclosure of which is hereby incorporated by reference in its entirety.

### BACKGROUND

The present inventive concepts relate generally to a semiconductor device and an electronic system including the same.

It is necessary to have a semiconductor device capable of storing a large amount of data in an electronic system which requires data storage. Therefore, studies have been conducted to increase data storage capacity of the semiconductor device. For example, as an approach to increase data storage capacity of the semiconductor device, a semiconductor device has been suggested to include three-dimensionally arranged memory cells instead of two-dimensionally arranged memory cells.

### SUMMARY

Some embodiments of the present inventive concepts provide a semiconductor device whose reliability is improved.

Some embodiments of the present inventive concepts provide an electronic system including a semiconductor device whose reliability is improved.

Objects of the present inventive concepts are not limited to those mentioned above, and other objects which have not been mentioned above will be clearly understood to those skilled in the art from the following description.

According to some embodiments of the present inventive concepts, a semiconductor device may comprise: a substrate; a stack structure that comprises a plurality of dielectric patterns and a plurality of conductive patterns that are vertically and alternately stacked on the substrate; a source conductive pattern on the stack structure; an upper conductive line between the stack structure and the source conductive pattern; and a plurality of vertical structures that penetrate (i.e., extend in or through) the stack structure and the upper conductive line and are electrically connected to the source conductive pattern. A thickness of the upper conductive line may be greater than a thickness of each of the conductive patterns. The vertical structure may comprise: a lower portion that penetrates the stack structure; and an upper portion that is connected to the lower portion and penetrates the upper conductive line. A minimum width of the upper portion may be greater than a minimum width of the lower portion.

According to some embodiments of the present inventive concepts, a semiconductor device may comprise: a peripheral circuit structure that comprises a substrate, a plurality of peripheral circuits integrated on the substrate, and a plurality of first bonding pads connected to the peripheral circuits; and a cell array structure that comprises a plurality of second bonding pads bonded to the first bonding pads. The cell array structure may comprise: a stack structure that comprises a plurality of dielectric patterns and a plurality of conductive patterns that are vertically and alternately stacked; a source conductive pattern on the stack structure; an upper conductive line between the stack structure and the source conductive pattern; a plurality of vertical structures that penetrate the stack structure and the upper conductive line and are electrically connected to the source conductive pattern; a plurality of bit lines that laterally extend across the stack structure and are connected to the vertical structures; a first interlayer dielectric layer between the upper conductive line and the source conductive pattern; and a second interlayer dielectric layer between the upper conductive line and the stack structure. A thickness of the upper conductive line may be greater than a thickness of each of the conductive patterns. The vertical structure may comprise: a lower portion that penetrates the stack structure; and an upper portion that is connected to the lower portion and penetrates the upper conductive line. A minimum width of the upper portion may be greater than a minimum width of the lower portion. The upper conductive line may be provided as a gate electrode of an erase control transistor that induces a gate induced drain leakage (GIDL).

According to some embodiments of the present inventive concepts, an electronic system may comprise: a semiconductor device that comprises a substrate and a cell array structure on the substrate; and a controller electrically connected through an input/output pad to the semiconductor device, the controller controlling the semiconductor device. The cell array structure may comprise: a stack structure that comprises a plurality of dielectric patterns and a plurality of conductive patterns that are vertically and alternately stacked on the substrate; a plurality of vertical structures that penetrate the stack structure; a source conductive pattern connected to the vertical structures on the stack structure; and an upper conductive line between the stack structure and the source conductive pattern. A thickness of the upper conductive line may be greater than a thickness of each of the conductive patterns. The vertical structure may comprise: a lower portion that penetrates the stack structure; and an upper portion that is connected to the lower portion and penetrates the upper conductive line. A minimum width of the upper portion may be greater than a minimum width of the lower portion.

### BRIEF DESCRIPTION OF DRAWINGS

The above and other aspects, features, and advantages of the present disclosure will be more clearly understood from the following detailed description, taken in combination with the accompanying drawings, wherein like reference numerals (when used) indicate corresponding elements throughout the several views, and in which:

FIG. 1 illustrates a simplified schematic diagram showing an electronic system that includes a semiconductor device according to some embodiments of the present inventive concepts;

FIG. 2 illustrates a simplified perspective view showing an electronic system that includes a semiconductor device according to some embodiments of the present inventive concepts;

FIGS. 3 and 4 illustrate simplified schematic cross-sectional views showing a semiconductor package according to some embodiments of the present inventive concepts;

FIG. 5 illustrates a schematic plan view showing a semiconductor device according to some embodiments of the present inventive concepts;

FIGS. 6A and 6B illustrate schematic cross-sectional views respectively taken along lines A-A′ and B-B′ of FIG. 5, showing a semiconductor device according to some embodiments of the present inventive concepts;

FIG. 7 illustrates an enlarged view showing section P of FIG. 6A; and

FIGS. 8 to 18 illustrate schematic cross-sectional views showing intermediate processes in an example method of fabricating a semiconductor device according to some embodiments of the present inventive concepts.

### DETAILED DESCRIPTION OF EMBODIMENTS

The following will now describe some illustrative embodiments of the present inventive concepts in conjunction with the accompanying drawings.

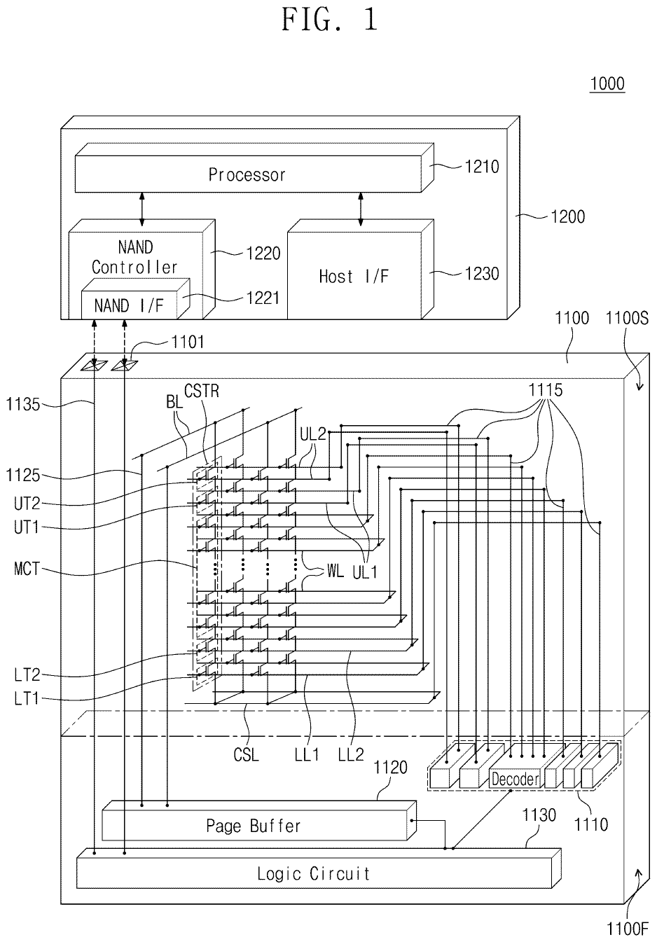

FIG. 1 illustrates a simplified schematic diagram showing an electronic system that includes a semiconductor device according to some embodiments of the present inventive concepts.

Referring to FIG. 1, an electronic system 1000 according to some embodiments of the present inventive concepts may include a semiconductor device 1100 and a controller 1200 electrically connected to the semiconductor device 1100. The electronic system 1000 may be a storage device that includes a single or a plurality of semiconductor devices 1100, or may be an electronic device that includes the storage device. For example, the electronic system 1000 may be a solid state drive (SSD) device, a universal serial bus (USB), a computing system, a medical apparatus, or a communication apparatus, each of which includes a single or a plurality of semiconductor devices 1100.

The semiconductor device 1100 may be a nonvolatile memory device, such as a NAND Flash memory device. The semiconductor device 1100 may include a first structure 1100F and a second structure 1100S on the first structure 1100F. In some embodiments, the first structure 1100F may be disposed on a side of the second structure 1100S.

The first structure 1100F may be a peripheral circuit structure that includes a decoder circuit 1110, a page buffer 1120, and a logic circuit 1130. The second structure 1100S may be a memory cell structure that includes bit lines BL, a common source line CSL, word lines WL, first and second gate upper lines UL1 and UL2, first and second gate lower lines LL1 and LL2, and memory cell strings CSTR between the bit line BL and the common source line CSL.

In the second structure 1100S, each of the memory cell strings CSTR may include lower transistors LT1 and LT2 adjacent to the common source line CSL, upper transistors UT1 and UT2 adjacent to the bit line BL, and memory cell transistors MCT disposed between the lower transistors LT1 and LT2 and the upper transistors UT1 and UT2. The number of the lower transistors LT1 and LT2 and of the upper transistors UT1 and UT2 may be variously changed in accordance with embodiments. The number of memory cell transistors MCT may be variously changed in accordance with embodiments.

In some embodiments, the upper transistors UT1 and UT2 may include a string selection transistor, and the lower transistors LT1 and LT2 may include a ground selection transistor. The gate lower lines LL1 and LL2 may be gate electrodes of the lower transistors LT1 and LT2, respectively. The word lines WL may be gate electrodes of the memory cell transistors MCT, and the gate upper lines UL1 and UL2 may be gate electrodes of the upper transistors UT1 and UT2, respectively.

In some embodiments, the lower transistors LT1 and LT2 may include a lower erase control transistor LT1 and a ground selection transistor LT2 that are connected in series. The upper transistors UT1 and UT2 may include a string selection transistor UT1 and an upper erase control transistor UT2 that are connected in series. The term “connected” (or “connecting,” or like terms, such as “contact” or “contacting”), as may be used herein, is intended to refer to a physical and/or electrical connection between two or more elements, and may include other intervening elements. As used herein, the term “and/or” includes any and all combinations of one or more of the associated listed items. One or both of the lower and upper erase control transistors LT1 and UT1 may be employed to perform an erase operation in which a gate induced drain leakage (GIDL) phenomenon is used to erase data stored in the memory cell transistors MCT.

The common source line CSL, the first and second gate lower lines LL1 and LL2, the word lines WL, and the first and second gate upper lines UL1 and UL2 may be electrically connected to the decoder circuit 1110 through first connection lines 1115 that extend from the first structure 1100F toward the second structure 1100S. The bit lines BL may be electrically connected to the page buffer 1120 through second connection lines 1125 that extend from the first structure 1100F to the second structure 1100S.

In the first structure 1100F, the decoder circuit 1110 and the page buffer 1120 may perform a control operation to at least one selection memory cell transistor among the plurality of memory cell transistors MCT. The logic circuit 1130 may control the decoder circuit 1110 and the page buffer 1120. The semiconductor device 1100 may communicate with the controller 1200 through one or more input/output pads 1101 electrically connected to the logic circuit 1130. The input/output pad(s) 1101 may be electrically connected to the logic circuit 1130 through a corresponding input/output connection line 1135 that extends from the first structure 1100F to the second structure 1100S.

Although not shown, the first structure 1100F may include a voltage generator. The voltage generator may produce program voltages, read voltages, pass voltages, and verification voltages that are required for operating the memory cell strings CSTR. The program voltage may be relatively higher (e.g., about 20 V to about 40 V) than the read voltage, the pass voltage, and the verification voltage.

In some embodiments, the first structure 1100F may include high-voltage transistors and low-voltage transistors. The decoder circuit 1110 may include pass transistors connected to the word lines WL of the memory cell strings CSTR. The pass transistors may include high-voltage transistors capable of withstanding high voltages such as program voltages applied to the word lines WL in a program operation. The page buffer 1120 may also include high-voltage transistors capable of withstanding high voltages.

The controller 1200 may include a processor 1210, a NAND controller 1220, and a host interface (I/F) 1230. According to some embodiments, the electronic system 1000 may include a plurality of semiconductor devices 1100, and in this case, the controller 1200 may control the plurality of semiconductor devices 1100.

The processor 1210 may control an overall operation of the electronic system 1000 that includes the controller 1200. The processor 1210 may operate based on predetermined firmware, and may control the NAND controller 1220 to access the semiconductor device 1100. The NAND controller 1220 may include a NAND interface 1221 that processes communication with the semiconductor device 1100. The NAND interface 1221 may be used to transfer therethrough a control command to control the semiconductor device 1100, data intended to be written on the memory cell transistors MCT of the semiconductor device 1100, and/or data intended to be read from the memory cell transistors MCT of the semiconductor device 1100. The host interface 1230 may provide the electronic system 1000 with communication with an external host (not explicitly shown). When a control command is received through the host interface 1230 from an external host, the semiconductor device 1100 may be controlled by the processor 1210 in response to the control command.

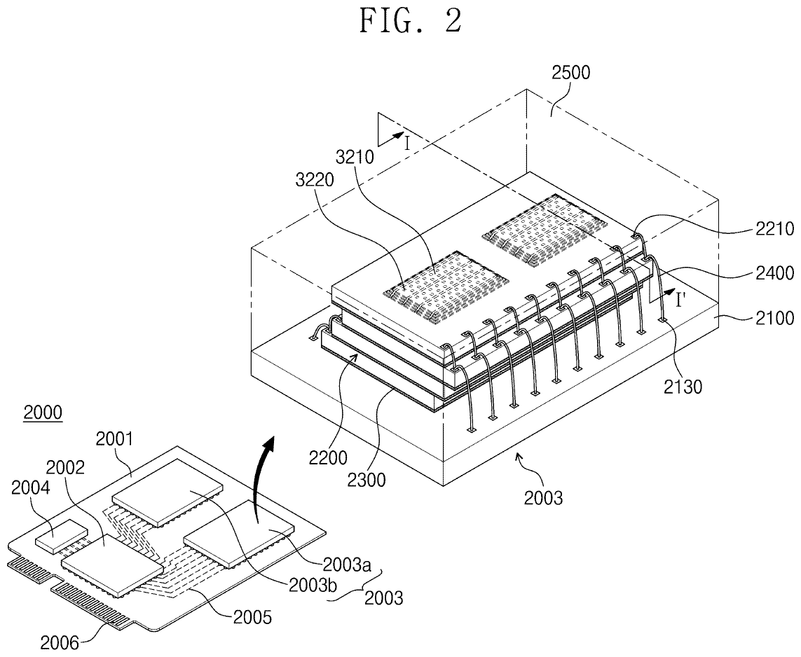

FIG. 2 illustrates a simplified perspective view showing an electronic system that includes a semiconductor device according to some embodiments of the present inventive concepts.

Referring to FIG. 2, an electronic system 2000 according to some embodiments of the present inventive concepts may include a mainboard 2001, and may also include a controller 2002, at least one semiconductor package 2003, and a dynamic random access memory (DRAM) 2004 that are mounted on the mainboard 2001. The semiconductor package 2003 and the DRAM 2004 may be connected to the controller 2002 through wiring patterns 2005 formed on the mainboard 2001.

The mainboard 2001 may include a connector 2006 including a plurality of pins that are coupled to an external host. The number and arrangement of the plurality of pins in the connector 2006 may be changed based on a communication interface between the electronic system 2000 and the external host. In some embodiments, the electronic system 2000 may communicate with the external host through one or more interfaces, for example, universal serial bus (USB), peripheral component interconnect express (PIC-Express), serial advanced technology attachment (SATA), and M-PHY for universal flash storage (UFS). In some embodiments, the electronic system 2000 may operate with power supplied through the connector 2006 from the external host. The electronic system 2000 may further include a power management integrated circuit (PMIC) by which the power supplied from the external host is distributed to the controller 2002 and the semiconductor package 2003.

The controller 2002 may write data to the semiconductor package 2003, may read data from the semiconductor package 2003, or may increase an operating speed of the electronic system 2000.

The DRAM 2004 may be a buffer memory that reduces a difference in speed between the external host and the semiconductor package 2003 that serves as a data storage space. The DRAM 2004 included in the electronic system 2000 may operate as a kind of cache memory, and may provide a space for temporary data storage in a control operation of the semiconductor package 2003. When the DRAM 2004 is included in the electronic system 2000, the controller 2002 may include not only a NAND controller for controlling the semiconductor package 2003, but also a DRAM controller for controlling the DRAM 2004.

The semiconductor package 2003 may include first and second semiconductor packages 2003a and 2003b that are spaced apart from each other on the mainboard 2001. Each of the first and second semiconductor packages 2003a and 2003b may be a semiconductor package including a plurality of semiconductor chips 2200. Each of the first and second semiconductor packages 2003a and 2003b may include a package substrate 2100, semiconductor chips 2200 on the package substrate 2100, adhesion layers 2300 disposed on bottom surfaces of the semiconductor chips 2200, connection structures 2400 that electrically connect the semiconductor chips 2200 to the package substrate 2100, and a molding layer 2500 on the package substrate 2100 that covers the semiconductor chips 2200 and the connection structures 2400. The term “covers” (or “covering,” or like terms), as may be used herein, is intended to broadly refer to an element, structure or layer that is on or over another element, structure or layer, either directly or with one or more other intervening elements, structures or layers therebetween.

The package substrate 2100 may be a printed circuit board including upper pads 2130 provided thereon. Each of the semiconductor chips 2200 may include one or more input/output pads 2210. The input/output pad 2210 may correspond to the input/output pad 1101 of FIG. 1. Each of the semiconductor chips 2200 may include stack structures 3210 and vertical structures 3220. Each of the semiconductor chips 2200 may include a semiconductor device which will be discussed below according to some embodiments of the present inventive concepts.

In some embodiments, the connection structure 2400 may be a bonding wire that electrically connects the input/output pad 2210 to the corresponding upper pad 2130. Therefore, in each of the first and second semiconductor packages 2003a and 2003b, the semiconductor chips 2200 may be electrically connected to each other in a bonding wire manner, and may be electrically connected to the upper pads 2130 of the package substrate 2100. In some embodiments, in each of the first and second semiconductor packages 2003a and 2003b, the semiconductor chips 2200 may be electrically connected to each other through connection structures such as through silicon vias (TSV) instead of the connection structures 2400 configured as bonding wires.

In some embodiments, the controller 2002 and the semiconductor chips 2200 may be included in a single package. For example, the controller 2002 and the semiconductor chips 2200 may be mounted on an interposer substrate other than the mainboard 2001, and may be connected to each other through wiring lines formed on the interposer substrate.

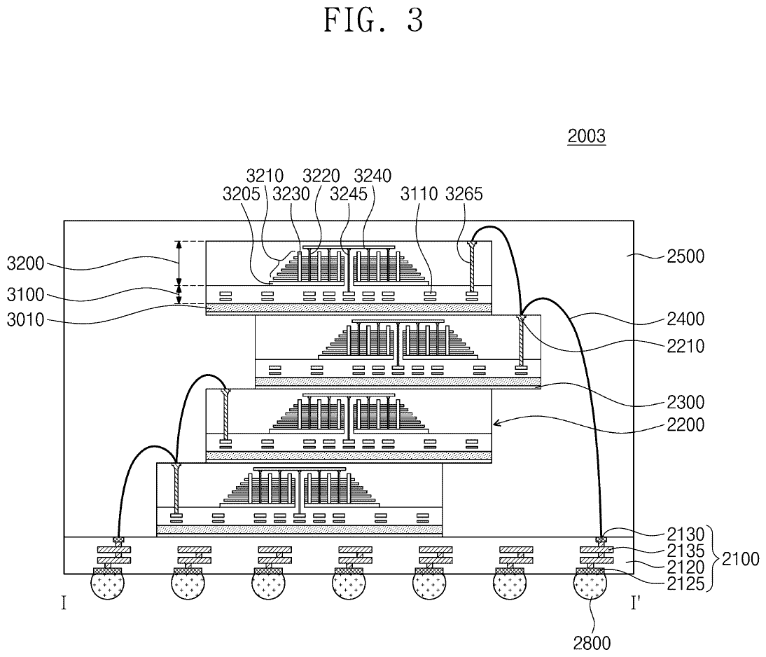

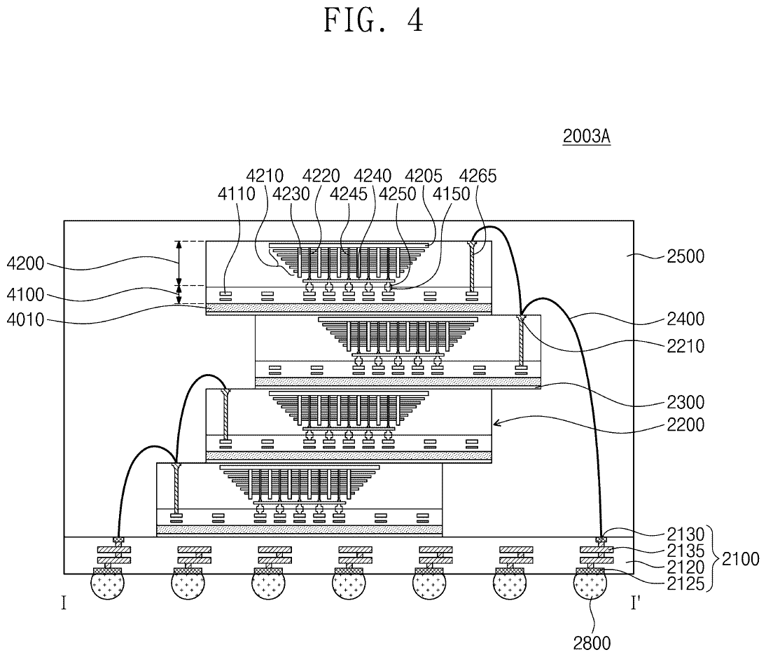

FIGS. 3 and 4 illustrate simplified schematic cross-sectional views showing a semiconductor package according to some embodiments of the present inventive concepts. FIGS. 3 and 4 each depict an example of the semiconductor package illustrated in FIG. 2, conceptually showing a section taken along line I-I′ of the semiconductor package illustrated in FIG. 2.

Referring to FIG. 3, a printed circuit board may be used as the package substrate 2100 of the semiconductor package 2003. The package substrate 2100 may include a package substrate body 2120, upper pads (see 2130 of FIG. 2) disposed on a top surface of the package substrate body 2120, lower pads 2125 disposed or exposed on a bottom surface of the package substrate body 2120, and internal lines 2135 by which the upper pads 2130 and the lower pads 2125 are electrically connected to each other in the package substrate body 2120. The upper pads 2130 may be electrically connected to the connection structures 2400. The lower pads 2125 may be connected through conductive connectors 2800 (e.g., solder bumps) to the wiring patterns 2005 of the mainboard 2001 in the electronic system 2000, as shown in FIG. 2.

Each of the semiconductor chips 2200 may include a semiconductor substrate 3010, and may also include a first structure 3100 and a second structure 3200 that are sequentially stacked on the semiconductor substrate 3010 in a vertical direction perpendicular to a surface of the semiconductor substrate 3010. The first structure 3100 may include a peripheral circuit region including peripheral wiring lines 3110. The second structure 3200 may include a source structure 3205, a stack structure 3210 on the source structure 3205, vertical structures 3220 and separation structures 3230 that penetrate (i.e., extend in the vertical direction in or through) the stack structure 3210, bit lines 3240 electrically connected to the vertical structures 3220, and cell contact plugs electrically connected to corresponding word lines (see WL of FIG. 1) of the stack structure 3210. Each of the first structure 3100, the second structure 3200, and the semiconductor chips 2200 may further include separation structures which are discussed above.

Each of the semiconductor chips 2200 may include one or more through wiring lines 3245 that extend in the vertical direction into the second structure 3200 and are electrically connected to the peripheral wiring lines 3110 of the first structure 3100. The through wiring line 3245 may be disposed outside the stack structure 3210, in a horizontal direction parallel to the surface of the semiconductor substrate 3010, and may further be disposed to penetrate the stack structure 3210. Each of the semiconductor chips 2200 may further include one or more input/output pads 2210 (see also 2210 of FIG. 2) electrically connected to the peripheral wiring lines 3110 of the first structure 3100.

Referring to FIG. 4, in a semiconductor package 2003A, each semiconductor chip 2200 may include a semiconductor substrate 4010, a first structure 4100 on the semiconductor substrate 4010, a second structure 4200 disposed on and wafer-bonded to the first structure 4100.

The first structure 4100 may include a peripheral circuit region including peripheral wiring lines 4110 and first bonding structures 4150. The second structure 4200 may include a source structure 4205, a stack structure 4210 between the source structure 4205 and the first structure 4100, vertical structures 4220 and separation structures 4230 that penetrate (i.e., extend in the vertical direction in or through) the stack structure 4210, and second bonding structures 4250 electrically connected to corresponding word lines (see WL of FIG. 1) of the stack structure 4210. For example, the second bonding structures 4250 may be electrically connected to corresponding vertical structures 4220 and corresponding word lines (see WL of FIG. 1) through the bit lines 4240 electrically connected to the vertical structures 4220 and through cell contact plugs electrically connected to the word lines WL. The first bonding structures 4150 of the first structure 4100 and the second bonding structures 4250 of the second structure 4200 may be bonded to each other while being in contact with each other. The first and second bonding structures 4150 and 4250 may have their bonding portions formed of, for example, copper (Cu).

Each of the first structures 4100, the second structures 4200, and the semiconductor chips 2200 may further include a source structure according to some embodiments discussed above. Each of the semiconductor chips 2200 may further include input/output pads (see 2210 of FIG. 2) electrically connected to the peripheral wiring lines 4110 of the first structure 4100.

The semiconductor chips 2200 of FIG. 3 or 4 may be electrically connected to each other through connection structures 2400 configured as bonding wires. In some embodiments, in one semiconductor package including the semiconductor chips 2200 of FIG. 3 or 4, the semiconductor chips 2200 may be electrically connected to each other through connection structures 3265 or 4265 including through electrodes such as through silicon vias (TSVs).

The first structure 3100 of FIG. 3 and the first structure 4100 of FIG. 4 may correspond to a peripheral circuit structure which will be discussed in the following embodiments, and the second structure 3200 of FIG. 3 and the second structure 4200 of FIG. 4 may correspond to a cell array structure which will be discussed in the following embodiments.

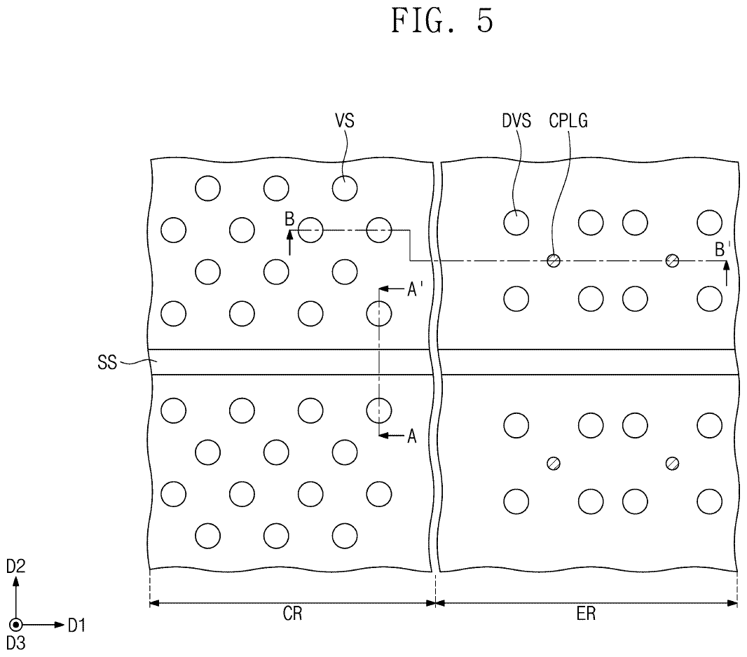

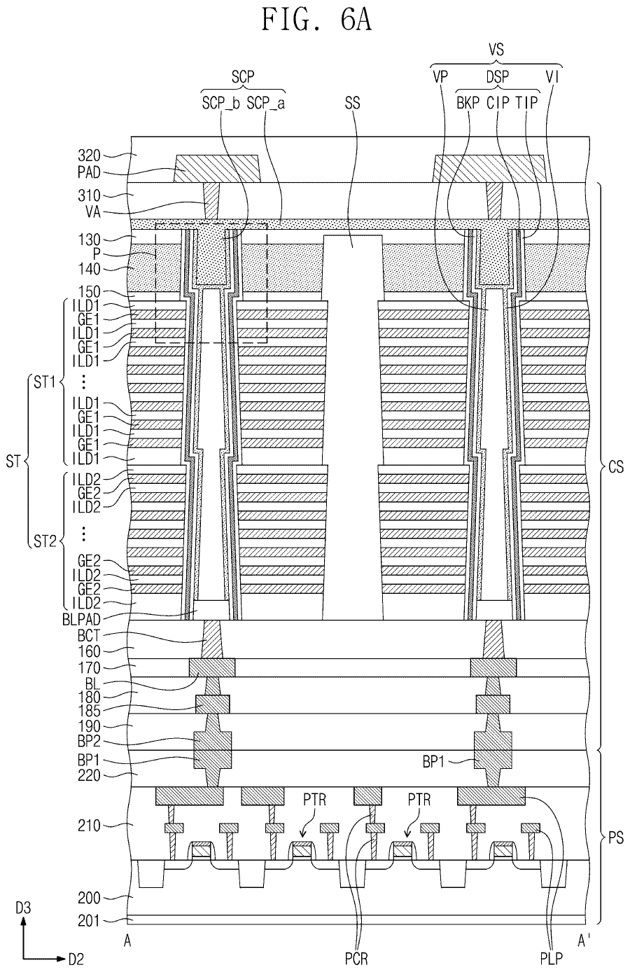

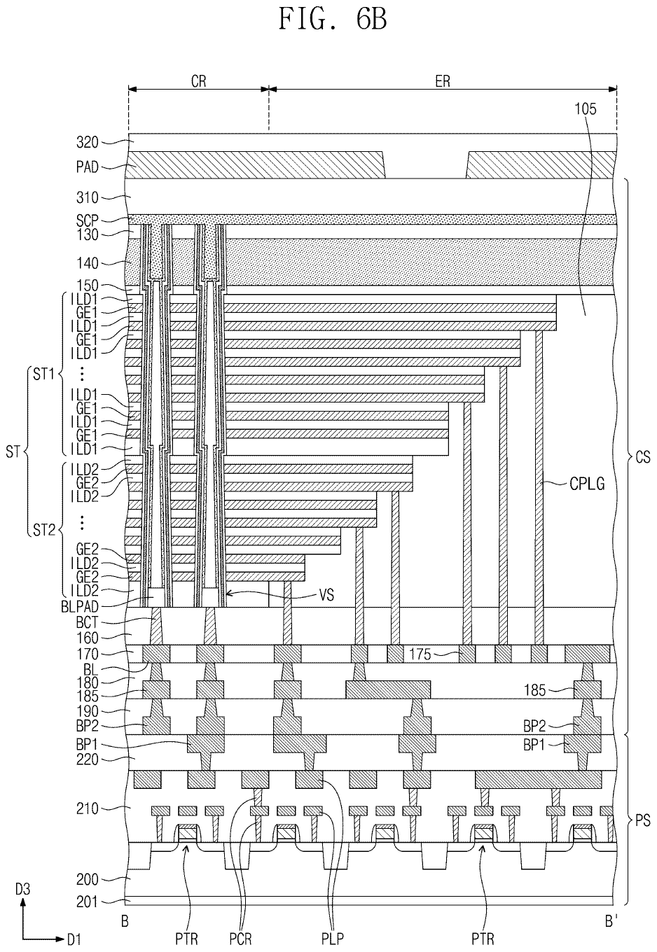

FIG. 5 illustrates a schematic plan view showing a semiconductor device according to some embodiments of the present inventive concepts. FIGS. 6A and 6B illustrate schematic cross-sectional views respectively taken along lines A-A′ and B-B′ of FIG. 5, showing a semiconductor device according to some embodiments of the present inventive concepts. FIG. 7 illustrates an enlarged view showing section P of FIG. 6A.

Referring to FIGS. 5, 6A, and 6B, a semiconductor device according to some embodiments may include a peripheral circuit structure PS on a substrate 200, and may also include a cell array structure CS on the peripheral circuit structure PS in a third direction D3 (i.e., vertical direction) perpendicular to a surface of the substrate 200.

According to some embodiments, as the cell array structure CS is bonded onto the peripheral circuit structure PS, it may be possible to increase a cell capacity per unit area of the semiconductor device according to the present inventive concepts. In addition, as the peripheral circuit structure PS and the cell array structure CS may be manufactured separately and then bonded to each other, subsequently described peripheral circuits PTR may be prevented from being damaged due to various heat treatment processes, and accordingly, it may be possible to improve reliability and electrical properties of the semiconductor device.

The peripheral circuit structure PS may include a substrate 200, peripheral circuits PTR that control a memory cell array, and peripheral interlayer dielectric layers 210 and 220 that cover the peripheral circuits PTR. The peripheral circuits PTR may be integrated on a top surface of the substrate 200. A surface dielectric layer 201 may be provided on a backside surface of the substrate 200.

The substrate 200 may be formed by depositing a semiconductor material. The substrate 200 may include, for example, at least one selected from silicon (Si), germanium (Ge), silicon germanium (SiGe), gallium arsenide (GaAs), indium gallium arsenide (InGaAs), aluminum gallium arsenide (AlGaAs), and a mixture thereof. The substrate 200 may include one or more of a semiconductor doped with impurities and an intrinsic semiconductor with no doped impurities. The substrate 200 may have at least one selected from a monocrystalline structure, an amorphous structure, and a polycrystalline structure.

The substrate 200 may have a top surface, which is parallel to a first direction D1 and a second direction D2 which intersects the first direction D1 and is perpendicular to the third direction D3. The first, second, and third directions D1, D2, and D3 may be orthogonal to each other.

The peripheral circuits PTR may be row and column decoders, a page buffer, and a control circuit. For example, the peripheral circuits PTR may include NMOS and PMOS transistors. Peripheral circuit lines PLP may be electrically connected through peripheral contact plugs PCR to the peripheral circuits PTR.

The peripheral contact plugs PCR may each have a width in the first direction D1 or the second direction D2, and for example, the width may increase in the third direction D3. The peripheral contact plugs PCR and the peripheral circuit lines PLP may include a conductive material such as metal.

The peripheral interlayer dielectric layers 210 and 220 may be provided on a top surface of the substrate 200. On the substrate 200, the peripheral interlayer dielectric layers 210 and 220 may cover the peripheral circuits PTR, the peripheral contact plugs PCR, and the peripheral circuit lines PLP. The peripheral contact plugs PCR and the peripheral circuit lines PLP may be electrically connected to the peripheral circuits PTR. The peripheral interlayer dielectric layers 210 and 220 may include one or more of a silicon oxide layer, a silicon nitride layer, a silicon oxynitride layer, and a low dielectric constant (low-k) dielectric layer.

First bonding pads BP1 may be disposed in an uppermost peripheral interlayer dielectric layer 220. The peripheral interlayer dielectric layer 220 may not cover top surfaces of the first bonding pads BP1. A top surface of the uppermost peripheral interlayer dielectric layer 220 may be substantially coplanar with those of the first bonding pads BP1. The first bonding pads BP1 may be electrically connected to the peripheral circuits PTR through the peripheral circuit lines PLP and the peripheral contact plugs PCR.

The cell array structure CS may be provided on the peripheral circuit structure PS. The cell array structure CS of the semiconductor device may include a cell array region CR and a peripheral region ER.

The cell array structure CS may include a memory cell array including three-dimensionally arranged memory cells. The cell array structure CS may include a source conductive pattern SCP, a stack structure ST, vertical structures VS, an upper conductive line 140, bit lines BL, and cell contact plugs CPLG.

The stack structure ST may include conductive patterns GE1 and GE2 and dielectric patterns ILD1 and ILD2 that are alternately stacked along the third direction D3 (or a vertical direction) perpendicular to the first and second directions D1 and D2 crossed with each other.

In some embodiments, the conductive patterns GE1 and GE2 may include first and second erase gate patterns adjacent to the source conductive pattern SCP, a ground selection gate pattern on the second erase gate pattern, a plurality of cell gate patterns stacked on the ground selection gate pattern in the third direction D3, and a string selection gate pattern on an uppermost cell gate pattern.

The conductive patterns GE1 and GE2 of the stack structure ST may be stacked to have an inverse stepwise structure on the peripheral region ER. For example, the conductive patterns GE1 and GE2 may have their lengths that increase in the first direction D1 with increasing distance in the third direction D3 from the peripheral circuit structure PS.

On the peripheral region ER, end portions of the conductive patterns GE1 and GE2 may be positioned at their locations horizontally and vertically different from each other. The end portions of the conductive patterns GE1 and GE2 may be correspondingly coupled to the cell contact plugs CPLG.

In some embodiments, the stack structure ST may include a first stack structure ST1 and a second stack structure ST2 on the first stack structure ST1. The first stack structure ST1 may include the first dielectric patterns ILD1 and the first conductive patterns GE1 that are alternately stacked in the third direction D3, and the second stack structure ST2 may include the second dielectric patterns ILD2 and the second conductive patterns GE2 that are alternately stacked in the third direction D3.

The second stack structure ST2 may be disposed between the first stack structure ST1 and the peripheral circuit structure PS. For example, the second stack structure ST2 may be provided on a bottom surface of a lowermost one of the first dielectric patterns ILD1 included in the first stack structure ST1. Although an uppermost one of the second dielectric patterns ILD2 included in the second stack structure ST2 is in contact with the lowermost one of the first dielectric patterns ILD1 included in the first stack structure ST1, the present inventive concepts are not limited thereto, and a single-layered dielectric layer may be provided between an uppermost one of the second conductive patterns GE2 included in the second stack structure ST2 and a lowermost one of the first conductive patterns GE1 included in the first stack structure ST1.

A lowermost one of the second conductive patterns GE2 included in the second stack structure ST2 may have a minimum length in the first direction D1, and an uppermost one of the first conductive patterns GE1 included in the first stack structure ST1 may have a maximum length in the first direction D1.

The first and second conductive patterns GE1 and GE2 may include a metallic material. For example, the first and second conductive patterns GE1 and GE2 may include at least one selected from metal (e.g., tungsten, molybdenum, nickel, copper, or aluminum), conductive metal nitride (e.g., titanium nitride or tantalum nitride), and transition metal (e.g., titanium or tantalum).

The first and second dielectric patterns ILD1 and ILD2 may include one or more of silicon oxide, silicon nitride, silicon oxynitride, and low-k dielectric. For example, the first and second dielectric patterns ILD1 and ILD2 may include high-density plasma (HDP) oxide or tetraethylorthosilicate (TEOS).

According to some embodiments, the semiconductor device may be a vertical NAND Flash memory device, and in this case, the first and second conductive patterns GE1 and GE2 of the stack structure ST may be used as the gate lower lines LL1 and LL2, the word lines WL, and the gate upper lines UL1 and UL2 discussed with reference to FIG. 1.

A planarized dielectric layer 105 may cover stepwise-structured end portions of the stack structure ST. The planarized dielectric layer 105 may have a substantially flat top surface. The planarized dielectric layer 105 may include a single dielectric layer or a plurality of stacked dielectric layers. The planarized dielectric layer 105 may have substantially flat top and bottom surfaces. The top surface of the planarized dielectric layer 105 may be substantially coplanar with that of the stack structure ST (or that of an uppermost first dielectric pattern ILD1), and the bottom surface of the planarized dielectric layer 105 may be substantially coplanar with that of the stack structure ST (or that of a lowermost dielectric pattern ILD2).

The upper conductive line 140 may be disposed on the stack structure ST. The upper conductive line 140 may be disposed on the uppermost first dielectric pattern ILD1 of the stack structure ST. For example, the upper conductive line 140 may include polysilicon, and may further include silicon oxide. The upper conductive line 140 may further include impurities having a first conductivity type, but the present inventive concepts are not limited thereto. Alternatively, the upper conductive line 140 may include metal.

In some embodiments, the upper conductive line 140 may be used as an erase control transistor that controls an erase operation by producing a gate induced drain leakage (GIDL) at an upper portion of a cell string (see CSTR of FIG. 1). For example, the upper conductive line 140 may be used in an erase operation that erases data stored in a cell string (see CSTR of FIG. 1).

On the cell array region CR, a plurality of vertical structures VS may penetrate the stack structure ST and the upper conductive line 140. When viewed in plan view, the vertical structures VS may be arranged in a straight or zigzag fashion along one direction.

In some embodiments, each of the vertical structures VS may be provided in a vertical channel hole that penetrates the stack structure ST. In some embodiments, the vertical channel hole may include a first vertical channel hole that penetrates the first stack structure ST1, and may also include a second vertical channel hole that penetrates the second stack structure ST2 and is connected to the first vertical channel hole.

Each of the vertical structures VS may include a first vertical extension in the first vertical channel hole and a second vertical extension in the second vertical channel hole. The first vertical extension and the second vertical extension may be a single structure that extends continuously without an interface. The first vertical extension may have a sidewall whose slope is constant from bottom to upper portions thereof. Likewise, the second vertical extension may have a sidewall whose slope is constant from lower to upper portions thereof. For example, each of the first and second vertical extensions may have a width in the first direction D1 or the second direction D2, and the width may decrease with increasing distance in the third direction D3 from the substrate 200. The first vertical extension and the second vertical extension may have different diameters at their connection portion. A step difference may be provided at the connection portion where the first vertical extension and the second vertical extension are connected to each other.

The present inventive concepts, however, are not limited thereto, and differently from that shown, each vertical structure VS may have three or more vertical extensions having step differences at two or more boundaries. Alternatively, each vertical structure VS may have a flat sidewall with no step difference.

Referring to FIGS. 6A and 7, each vertical structure VS may extend in the third direction D3 perpendicular to the top surface of the substrate 200 to penetrate the stack structure ST and the upper conductive line 140, being connected to the source conductive pattern SCP.

Each of the vertical structures VS may include a vertical channel pattern VP, a data storage pattern DSP, and a vertical dielectric pattern VI. For example, the vertical dielectric pattern VI may include at least one material selected from silicon oxide and silicon nitride, although embodiments are not limited thereto.

For example, the vertical channel pattern VP may have a macaroni shape or a pipe shape whose top and bottom ends are closed. The vertical channel pattern VP may have an inner sidewall that defines an internal space and an outer sidewall adjacent to the stack structure ST. The vertical channel pattern VP may surround an outer sidewall and a top surface of the vertical dielectric pattern VI. The term “surround” (or “surrounds,” or like terms), as may be used herein, is intended to broadly refer to an element, structure or layer that extends around, envelops, encircles, or encloses another element, structure or layer on all sides, although breaks or gaps may also be present. Thus, for example, a material layer having voids or gaps therein may still “surround”another layer which it encircles.

The vertical channel pattern VP may include a semiconductor material, such as silicon (Si), germanium (Ge), or a mixture thereof. For example, the vertical channel pattern VP may include polycrystalline silicon. The vertical channel pattern VP including a semiconductor material may be used as channels of the upper transistors UT1 and UT2, of the memory cell transistors MCT, and of the lower transistors LT1 and LT2, all of which transistors are discussed with reference to FIG. 1. The vertical channel pattern VP may be adjacent horizontally (e.g., in the first direction D1 or the second direction D2) to the upper conductive line 140, and may be used as a channel of an erase control transistor for which the upper conductive line 140 is utilized.

The data storage pattern DSP may extend in the third direction D3 and surround an outer sidewall of the vertical channel pattern VP. The data storage pattern DSP may have a macaroni or a pipe shape whose top end is open. The data storage pattern DSP may be formed of a single thin layer or a plurality of thin layers. In some embodiments of the present inventive concepts, the data storage pattern DSP may include a tunnel dielectric pattern TIP, a storage charge pattern CIP, and a blocking dielectric pattern BKP, which are sequentially stacked on a sidewall of the vertical channel pattern VP and are used as a data storage layer of a NAND Flash memory device. For example, the charge storage pattern CIP may be a trap dielectric layer, a floating gate electrode, or a dielectric layer including conductive nano-dots. The tunnel dielectric pattern TIP may include one of several suitable materials having a band gap greater than that of the charge storage pattern CIP, and the blocking dielectric pattern BKP may be a high dielectric constant (high-k) dielectric layer such as an aluminum oxide layer or a hafnium oxide layer.

The vertical structure VS may include a lower portion that penetrates the stack structure ST, and may also include an upper portion that is connected to the lower portion and penetrates first and second interlayer dielectric layers 130 and 150 and the upper conductive line 140. For example, the lower portion of the vertical structure VS may include the first vertical extension and the second vertical extension that penetrate the first stack structure ST1 and the second stack structure ST2 discussed above. The upper portion of the vertical structure VS may refer to a portion that continuously extends, without an interface, onto the stack structure ST from the lower portion of the vertical structure VS.

The lower portion of the vertical structure VS may have a minimum width W3 at the same level as that of the top surface of the stack structure ST. For example, the lower portion of the vertical structure VS may have a minimum width W3 in the second direction D2 at the same level as that of the top surface of the uppermost first dielectric pattern ILD1.

The upper portion of the vertical structure VS may have a minimum width W4 greater than the minimum width W3 of the lower portion of the vertical structure VS. For example, the upper portion of the vertical structure VS may have a width greater than the minimum width W3 of the lower portion of the vertical structure VS, and a step difference may be formed at a level (e.g., the same as a level of the top surface of the uppermost first dielectric pattern ILD1) where the lower portion of the vertical structure VS is connected to the upper portion of the vertical structure VS. The upper portion of the vertical structure VS may have a minimum width W4 at the same level as that of a top surface of the first interlayer dielectric layer 130. For example, widths of the upper and lower portions of the vertical structure VS may each be a width in a horizontal direction (e.g., the second direction D2).

On a top surface of each vertical structure VS, a groove GR may be formed that is recessed toward the substrate 200. For example, the groove GR may be an internal space surrounded by an inner lateral surface of the vertical channel pattern VP. In addition, an uppermost end portion VP_U of the vertical channel pattern VP and an uppermost end portion DSP_U of the data storage pattern DSP may be substantially coplanar with each other, and may be located at a level higher than that of a top surface VI_U of the vertical dielectric pattern VI in the third direction D3, relative to an upper surface of the substrate 200 as a reference layer. The uppermost end portion VP_U of the vertical channel pattern VP and the uppermost end portion DSP_U of the data storage pattern DSP may be located at a level higher than that of a top surface 140_U of the upper conductive line 140 in the third direction D3, relative to the upper surface of the substrate 200.

A horizontal width of the groove GR may gradually increase with decreasing distance from the vertical dielectric pattern VI; that is, the horizontal width of the groove GR may increase as the groove GR gets closer to the top surface VI_U of the vertical dielectric pattern VI. The width of the groove GR may gradually increase with decreasing distance from the stack structure ST or the substrate 200. For example, the groove GR may have a first width W1 at a top end thereof and a second width W2 at a bottom end thereof, and the second width W2 may be greater than the first width W1. The first width W1 and the second width W2 of the groove GR may refer to widths in the second direction D2 at top and bottom ends, respectively.

A thickness T1 in the third direction D3 of the upper conductive line 140 may be greater than a thicknesses T2 in the third direction D3 of the conductive patterns GE1 and GE2 of the stack structure ST. For example, the thicknesses T2 of the conductive patterns GE1 and GE2 may be substantially similar to each other, and may have a similar value to that of the thickness T2 of an uppermost conductive pattern GE1T among the conductive patterns GE1 and GE2. The thickness T1 of the upper conductive line 140 may be greater than the thickness T2 of the uppermost conductive pattern GE1T, and for example, may be greater than about twice the thickness T2 of the uppermost conductive pattern GE1T. For example, the thickness T1 of the upper conductive line 140 may range from about 20 nm to about 1 μm.

A horizontal dielectric pattern HP may be disposed between the data storage pattern DSP and the conductive patterns GE1 and GE2 of the stack structure ST. The horizontal dielectric pattern HP may extend from sidewalls of the conductive patterns GE1 and GE2 onto top and bottom surfaces of the conductive patterns GE1 and GE2. The horizontal dielectric pattern HP may include a high-k dielectric layer. For example, the horizontal dielectric pattern HP may include metal oxide containing a first metal, and the first metal may be one of aluminum (Al) and hafnium (Hf).

A high-k dielectric layer may not be separately disposed between the upper conductive line 140 and the data storage pattern DSP. For example, the upper conductive line 140 may be in contact with the data storage pattern DSP. In addition, the upper conductive line 140 may not include the metal oxide discussed above. In other words, the upper conductive line 140 may not include the first metal (e.g., aluminum or hafnium).

According to some embodiments of the present inventive concepts, the upper conductive line 140 may be provided as a gate electrode of an erase transistor that induces a gate induced drain leakage (GIDL) on the stack structure ST. The thickness T1 of the upper conductive line 140 may be greater than the thicknesses T2 of the conductive patterns GE1 and GE2 in the stack structure ST, and the thickness T1 of the upper conductive line 140 may be formed largely, which may result in an increase in efficiency of gate induced drain leakage. Moreover, a high-k dielectric layer may not be separately disposed between the upper conductive line 140 and the data storage pattern DSP, and thus the efficiency of gate induced drain leakage may be more increased. Accordingly, the semiconductor device according to some embodiments of the present inventive concepts may achieve improved reliability.

The source conductive pattern SCP may be disposed on the vertical structures VS and a separation structure SS which will be discussed below, and may be electrically connected to the vertical structures VS. The source conductive pattern SCP may include a first portion SCP_a that extends along the first direction D1 and the second direction D2 on the upper conductive line 140, and may also include a second portion SCP_b that has a connection with the first portion SCP_a and penetrates at least a portion of the upper conductive line 140. The second portion SCP_b may protrude toward the groove GR.

The first portion SCP_a may be in contact with the uppermost end portion DSP_U of the data storage pattern DSP and the uppermost end portion VP_U of the vertical channel pattern VP. The second portion SCP_b may overlap the groove GR when viewed in plan view. As used herein, “an element A overlapping an element B in a direction X” (or similar language) means that there is at least one line that extends in the direction X and intersects both the elements A and B. The second portion SCP_b may protrude toward the groove GR of the vertical structure VS, and the vertical channel structure VS may surround the second portion SCP_b. The second portion SCP_b may be in contact with an inner lateral surface of the vertical channel pattern VP, which inner lateral surface constitutes the groove GR. The second portion SCP_b may be vertically spaced apart from the vertical dielectric pattern VI, and a bottom surface of the second portion SCP_b may be located at a level higher, in the third direction D3, than that of the top surface VI_U of the vertical dielectric pattern VI, relative to the upper surface of the substrate 200. Additionally, the second portion SCP_b may be horizontally adjacent to the upper conductive line 140, and the bottom surface of the second portion SCP_b may be located at a level higher than that of a top surface of the uppermost conductive pattern GE1T among the conductive patterns GE1 and GE2 in the stack structure ST.

For example, the source conductive pattern SCP may include polysilicon, and may further include impurities having the first conductivity type (e.g., n-type). For example, the source conductive pattern SCP may further include at least one selected from phosphorus (P), arsenic (As), and antimony (Sb). A concentration of the impurity having the first conductivity type in the source conductive pattern SCP may be different from a concentration of impurities having the first conductivity type in the vertical channel pattern VP. For example, the source conductive pattern SCP may include impurities having the first conductivity type at a first concentration, and the vertical channel pattern VP may include impurities having the first conductivity type at a second concentration different from the first concentration. For example, the first concentration may be greater than the second concentration.

The first interlayer dielectric layer 130 may be disposed on the upper conductive line 140. The first interlayer dielectric layer 130 may cover the top surface 140_U of the upper conductive line 140. The first interlayer dielectric layer 130 may be disposed between the upper conductive line 140 and the source conductive pattern SCP. The second interlayer dielectric layer 150 may be disposed between the upper conductive line 140 and the stack structure ST. For example, the first and second interlayer dielectric layers 130 and 150 may include one or more of silicon oxide, silicon nitride, and silicon oxynitride.

Referring back to FIGS. 5, 6A, and 6B, first, second, third, and fourth lower dielectric layers 160, 170, 180, and 190 may be sequentially disposed on the bottom surface of the planarized dielectric layer 105 and the bottom surface of the stack structure ST. The first lower dielectric layer 160 may cover bottom surfaces of the vertical structures VS. For example, the first, second, third, and fourth lower dielectric layers 160, 170, 180, and 190 may include one or more of silicon oxide and silicon oxynitride.

The vertical structures VS may be provided therebetween with a separation structure SS that extends along the first direction D1 from the cell array region CR toward the peripheral region ER. The separation structure SS may penetrate vertically (e.g., in the third direction D3) through the stack structure ST and the upper conductive line 140. A top surfaces of the separation structure SS may be located at a level lower than that of a top surface of the first interlayer dielectric layer 130. For example, the separation structure SS may include one or more of silicon oxide and silicon oxynitride.

A bit-line conductive pad BLPAD may be formed on a bottom end of the vertical structure VS, and bit-line contact plugs BCT may penetrate the first lower dielectric layer 160 to come into coupling engagement with the bit-line conductive pad BLPAD. The bit-line conductive pad BLPAD may include an impurity-undoped semiconductor material, an impurity-doped semiconductor material, or a conductive material.

On the peripheral region ER, cell contact plugs CPLG may penetrate the first lower dielectric layer 160 and the planarized dielectric layer 105 to come into coupling engagement with pad portions of the first and second conductive patterns GE1 and GE2. The cell contact plugs CPLG may have their vertical lengths that decrease with decreasing distance from the cell array region CR. The cell contact plugs CPLG may have their bottom surfaces substantially coplanar with each other.

Each of the cell contact plugs CPLG may include a barrier metal layer including conductive metal nitride (e.g., titanium nitride or tantalum nitride) and a metal layer including metal (e.g., tungsten, titanium, or tantalum).

On the cell array region CR, bit lines BL may be provided in the second lower dielectric layer 170. The bit lines BL may extend in the second direction D2, while running across the stack structure ST. The bit lines BL may be electrically connected through the bit-line contact plugs BCT to the vertical structures VS.

On the peripheral region ER, first lower conductive lines 175 may be provided in the second lower dielectric layer 170. On the peripheral region ER, the first lower conductive lines 175 may be coupled to the cell contact plugs CPLG.

Second lower conductive lines 185 may be provided in the third lower dielectric layer 180. On the cell region CR, the second lower conductive lines 185 may be electrically connected to the bit lines BL. On the peripheral region ER, the second lower conductive lines 185 may be electrically connected to the first lower conductive lines 175.

A second bonding pad BP2 may be provided in the fourth lower dielectric layer 190. A plurality of second bonding pads BP2 may be electrically connected to the second lower conductive lines 185. The bit line BL, the first and second lower conductive lines 175 and 185, and the second bonding pads BP2 may be formed of aluminum, copper, or tungsten.

A bonding method may be employed to electrically and physically connect the second bonding pads BP2 to the first bonding pads BP1. For example, the second bonding pads BP2 may be in direct contact with the first bonding pads BP1.

The second bonding pads BP2 may include the same metallic material as that of the first bonding pads BP1. The second bonding pads BP2 may have substantially the same shape, width, and area as those of the first bonding pads BP1.

An upper dielectric layer 310 may cover the source conductive pattern SCP. An upper via VA may be disposed to penetrate the upper dielectric layer 310 to come into electrical connection with the source conductive pattern SCP.

Wiring pads PAD may be disposed on the upper dielectric layer 310. A capping dielectric layer 320 may be disposed on the upper dielectric layer 310, and the capping dielectric layer 320 may cover the wiring pads PAD.

The capping dielectric layer 320 may be disposed on a front surface of the upper dielectric layer 310. The capping dielectric layer 320 may be, for example, a silicon nitride layer or a silicon oxynitride layer. Although not shown, for example, a passivation layer may be additionally disposed on the capping dielectric layer 320. For example, the passivation layer (not shown) may include a polyimide-based material, such as photosensitive polyimide (PSPI).

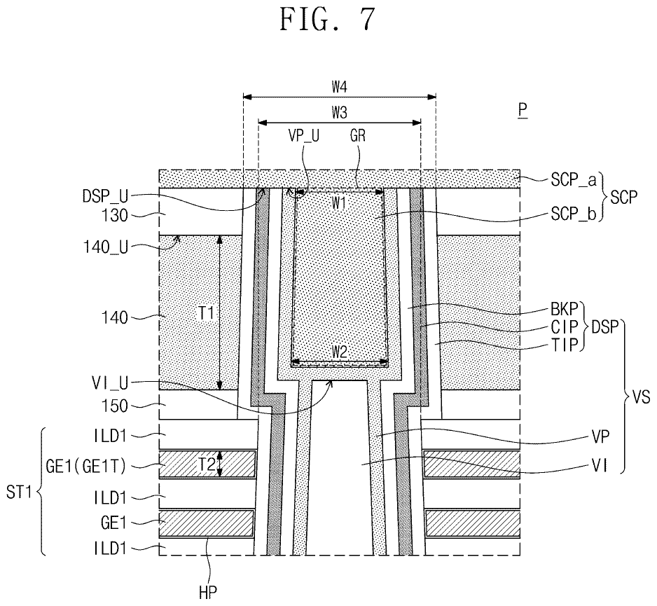

FIGS. 8 to 18 illustrate schematic cross-sectional views showing intermediate processes in an illustrative method of fabricating a semiconductor device according to some embodiments of the present inventive concepts. FIGS. 8 to 18 may correspond to FIG. 6A.

Referring to FIG. 8, a peripheral circuit structure PS may be provided which includes peripheral circuits PTR formed on a substrate 200.

For example, the formation of the peripheral circuit structure PS may include forming in the substrate 200 a device isolation layer that defines an active area, forming the peripheral circuits PTR on the active area on the substrate 200, forming peripheral contact plugs PCR, peripheral circuit lines PLP, first bonding pads BP1 that are electrically connected to the peripheral circuits PTR, and forming peripheral interlayer dielectric layers 210 and 220 on the substrate 200 that cover the peripheral contact plugs PCR, the peripheral circuit lines PLP, and the first bonding pads BP1.

The substrate 200 may be formed by depositing a semiconductor material. The substrate 200 may include, for example, at least one selected from silicon (Si), germanium (Ge), silicon germanium (SiGe), gallium arsenic (GaAs), indium gallium arsenide (InGaAs), aluminum gallium arsenide (AlGaAs), and a mixture thereof. The substrate 200 may include one or more of a semiconductor doped with impurities and an intrinsic semiconductor with no doped impurities. The substrate 200 may comprise at least one material selected from a monocrystalline structure, an amorphous structure, and a polycrystalline structure. A surface dielectric layer 201 may be provided on a backside surface of the substrate 200.

Row and column decoders, page buffers, and control circuits may be formed as the peripheral circuits PTR on the substrate 200. The peripheral circuits PTR may include metal oxide semiconductor (MOS) transistors each of which uses the substrate 200 as a channel.

The peripheral interlayer dielectric layers 210 and 220 may include a single dielectric layer that covers the peripheral circuits PTR or a plurality of stacked dielectric layers that cover the peripheral circuits PTR. For example, the peripheral interlayer dielectric layers 210 and 220 may include a plurality of lower dielectric layers and etch stop layers between the lower dielectric layers. The peripheral interlayer dielectric layers 210 and 220 may include one or more of a silicon oxide layer, a silicon nitride layer, a silicon oxynitride layer, and a low-k dielectric layer.

The peripheral contact plugs PCR may be formed to penetrate portions of the peripheral interlayer dielectric layers 210 and 220 to come into connection with the peripheral circuits PTR. The peripheral circuit lines PLP may be formed by depositing a conductive layer and patterning the conductive layer.

The first bonding pads BP1 may be formed in an uppermost one 220 of the peripheral interlayer dielectric layers 210 and 220. The first bonding pads BP1 may be electrically connected to the peripheral circuits PTR through the peripheral contact plugs PCR and the peripheral circuit lines PLP.

A damascene process may be used to form the first bonding pads BP1. The first bonding pads BP1 may have their top surfaces substantially coplanar with that of the uppermost peripheral interlayer dielectric layer 220. In this description below, the phrase “substantially coplanar with” may imply that a planarization process is performed. The planarization process may include, for example, a chemical mechanical polishing (CMP) process or an etch-back process, although embodiments are not limited thereto.

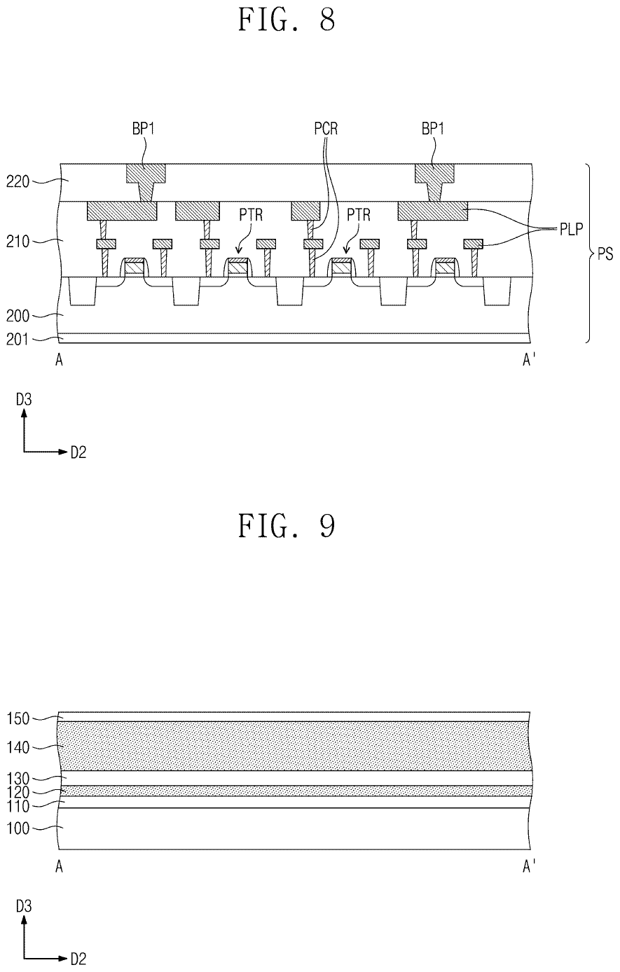

Referring to FIG. 9, a sub-substrate 100 may be provided. The sub-substrate 100 may include, for example, at least one selected from silicon (Si), germanium (Ge), silicon germanium (SiGe), gallium arsenic (GaAs), indium gallium arsenic (InGaAs), aluminum gallium arsenic (AlGaAs), and a mixture thereof.

A preliminary interlayer dielectric layer 110, a preliminary semiconductor layer 120, a first interlayer dielectric layer 130, an upper conductive line 140, and a second interlayer dielectric layer 150 may be sequentially formed on the sub-substrate 100. The preliminary interlayer dielectric layer 110 and the first and second interlayer dielectric layers 130 and 150 may include, for example, at least one material selected from silicon oxide, silicon nitride, and silicon oxynitride. For example, the preliminary semiconductor layer 120 and the upper conductive line 140 may include polysilicon.

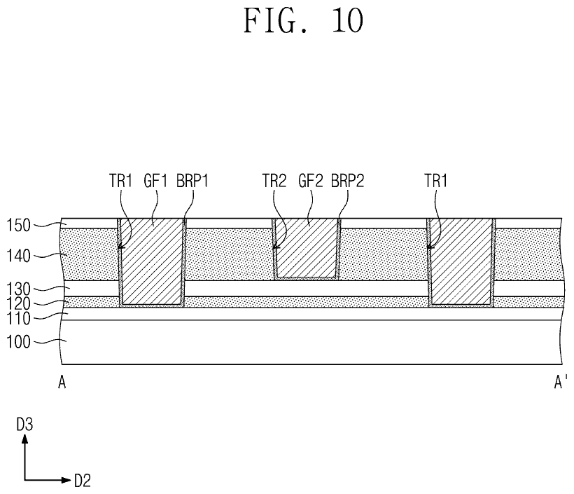

Referring to FIG. 10, first trenches TR1 may be formed to penetrate the first and second interlayer dielectric layers 130 and 150, the upper conductive line 140, and the preliminary semiconductor layer 120. In addition, a second trench TR2 may be formed to penetrate the second interlayer dielectric layer 150 and the upper conductive line 140. The first and second trenches TR1 and TR2 may be formed by repeatedly performing a patterning process. For example, bottom ends of the first trenches TR1 may be located at a level lower, in the third direction D3, than that of a bottom end of the second trench TR2, relative to a surface of the sub-substrate 100. For example, when viewed in plan view, the first and second trenches TR1 and TR2 may each have a circular or oval shape having a major axis in a first direction D1 or a second direction D2.

First barrier patterns BRP1 and first gap-fill patterns GF1 may be sequentially formed to fill the first trenches TR1. The term “fill” (or “fills,” or like terms) is intended to refer to either completely filling a defined space (e.g., the first and second trenches TR1, TR2) or partially filling the defined space; that is, the defined space need not be entirely filled but may, for example, be partially filled or have voids or other spaces throughout. Each of the first barrier patterns BRP1 may conformally cover an inner wall of the first trench TR1, and the first gap-fill patterns GF1 may be correspondingly formed on the first barrier patterns BRP1. The term “conformally” (or “conformal,” or like terms), as may be used herein in the context of a material layer or coating, is intended to refer broadly to a material layer or coating having a substantially uniform cross-sectional thickness relative to the contour of a surface to which the material layer is applied. A second barrier pattern BRP2 and a second gap-fill pattern GF2 may be sequentially formed to fill the second trench TR2. The second barrier pattern BRP2 may conformally cover an inner wall of the second trench TR2, and the second gap-fill pattern GF2 may be formed on the second barrier pattern BRP2. For example, the first and second barrier patterns BRP1 and BRP2 may include conductive metal nitride (e.g., titanium nitride or tantalum nitride), and the first and second gap-fill patterns GF1 and GF2 may include metal (e.g., tungsten, titanium, or tantalum).

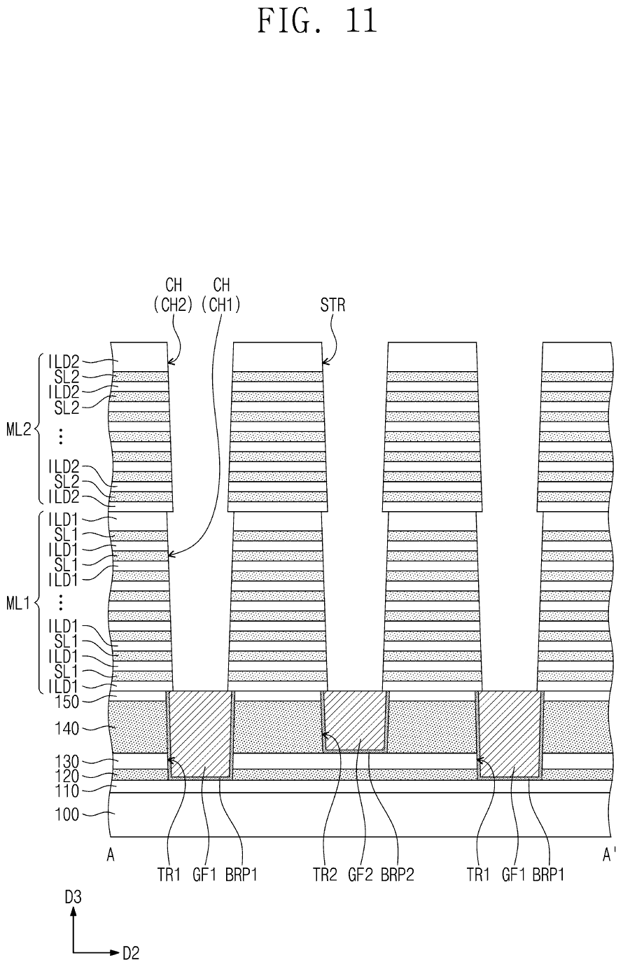

Referring to FIG. 11, first and second mold structures ML1 and ML2 may be formed on the second interlayer dielectric layer 150.

The formation of the first mold structure ML1 may include vertically and alternately stacking first dielectric patterns ILD1 and first sacrificial layers SL1. In the first mold structure ML1, the first sacrificial layers SL1 may be formed of a material capable of being etched with etch selectivity with respect to the first dielectric patterns ILD1. For example, the first sacrificial layers SL1 may be formed of a dielectric material different from that of the first dielectric patterns ILD1. For example, the first sacrificial layers SL1 may include silicon nitride, and the first dielectric patterns ILD1 may include one or more of silicon oxide, silicon oxynitride, and low-k dielectric.

The first dielectric patterns ILD1 and the first sacrificial layers SL1 may be deposited using, for example, thermal chemical vapor deposition (CVD), plasma enhanced CVD, physical CVD, or atomic layer deposition (ALD).

In the first mold structure ML1, a patterning process may be performed to form first channel holes CH1. For example, when viewed in plan view, the first channel holes CH1 may each have a circular or oval shape having a major axis in the first direction D1 or the second direction D2. In the first mold structure ML1, a patterning process may be performed to form a separation trench STR. For example, when viewed in plan, the separation trench STR may have a bar or trench shape. While the patterning process is performed, the first and second gap-fill patterns GF1 and GF2 may be used as an etch stop layer.

The second mold structure ML2 may be formed on the first mold structure ML1. The formation of the second mold structure ML2 may be substantially the same as the formation of the first mold structure ML1. For example, the formation of the second mold structure ML2 may include vertically and alternately stacking second dielectric patterns ILD2 and second sacrificial layers SL2 on the first mold structure ML1.

The second sacrificial layers SL2 may be formed of the same material as that of the first sacrificial layers SL1 and may have substantially the same thickness as that of the first sacrificial layers SL1. The second sacrificial layers SL2 may be formed of a dielectric material different from that of the second dielectric patterns ILD2. The second sacrificial layers SL2 may be formed of the same material as that of the first sacrificial layers SL1. For example, the second sacrificial layers SL2 may be formed of a silicon nitride layer, and the second dielectric patterns ILD2 may be formed of a silicon oxide layer.

The second dielectric patterns ILD2 and the second sacrificial layers SL2 may be deposited using, for example, thermal chemical vapor deposition (CVD), plasma enhanced CVD, physical CVD, or atomic layer deposition (ALD).

In the second mold structure ML2, a patterning process may be performed to form second channel holes CH2. For example, when viewed in plan view, the second channel holes CH2 may each have a circular or oval shape having a major axis in the first direction D1 or the second direction D2. The second channel holes CH2 may be connected to the first channel holes CH1, and channel holes CH may be formed to penetrate the first and second mold structures ML1 and ML2. In the second mold structure ML2, a patterning process may be additionally performed to form a separation trench STR to penetrate the first and second mold structures ML1 and ML2.

While the patterning process is performed, the first and second gap-fill patterns GF1 and GF2 and the first and second barrier patterns BRP1 and BRP2 may penetrate at least a portion of the preliminary interlayer dielectric layer 110. In addition, bottom ends of the first and second trenches TR1 and TR2 may be located at a lowered level.

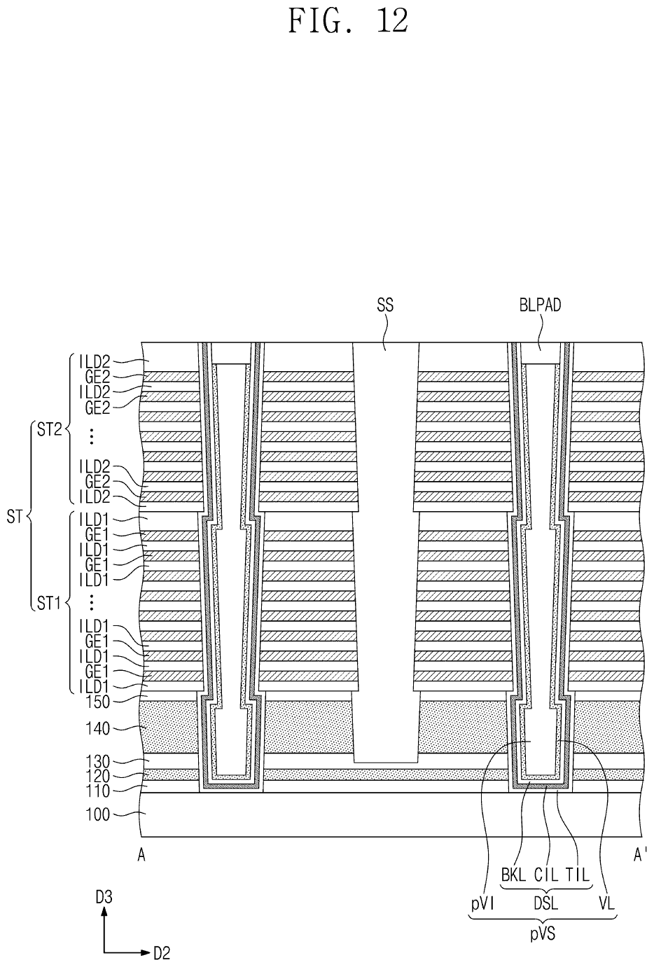

Referring to FIGS. 11 and 12, it may be possible to selectively remove the first and second gap-fill patterns GF1 and GF2 and the first and second barrier patterns BRP1 and BRP2 that fill the first and second trenches TR1 and TR2. For example, a wet etching process may be performed to remove the first and second gap-fill patterns GF1 and GF2 and the first and second barrier patterns BRP1 and BRP2.

A preliminary vertical structure pVS may be formed to fill the channel hole CH and the first trench TR1. The formation of the preliminary vertical structure pVS may include sequentially depositing a data storage layer DSL and a vertical channel layer VL in the channel hole CH and the first trench TR1, filling the channel hole CH and the first trench TR1 with a preliminary vertical dielectric pattern pVI, and on an uppermost second dielectric pattern ILD2, etching and planarizing the data storage layer DSL and the vertical channel layer VL. Afterwards, bit-line conductive pads BLPAD may be correspondingly formed on top ends of the vertical channel layer VL and the preliminary vertical dielectric pattern pVI. The bit-line conductive pads BLPAD may be an impurity-doped region or formed of a conductive material. The bit-line conductive pads BLPAD may have their top surfaces coplanar with that of the uppermost second dielectric pattern ILD2. The data storage layer DSL may include a tunnel dielectric layer TIL, a charge storage layer CIL, and a blocking dielectric layer BKL that are sequentially stacked.

For example, chemical vapor deposition (CVD) or atomic layer deposition (ALD) may be used to deposit the data storage layer DSL and the vertical channel layer VL each of which has a constant thickness. For example, the charge storage layer CIL may be a trap dielectric layer, a floating gate electrode, or a dielectric layer including conductive nano-dots. The tunnel dielectric layer TIL may include one of several suitable materials whose bandgap is greater than that of the charge storage layer CIL, and the blocking dielectric layer BKL may be a high-k dielectric layer such as an aluminum oxide layer or a hafnium oxide layer. For example, the preliminary vertical dielectric pattern pVI may include at least one selected from silicon oxide and silicon nitride. For example, the vertical channel layer VL may include a semiconductor material such as silicon (Si), germanium (Ge), or a mixture thereof.

A separation structure SS may be formed to fill the separation trench STR and the second trench TR2. The separation structure SS may have a multi-layered structure or a single-layered structure. For example, the separation structure SS may include one or more of silicon oxide and silicon oxynitride.

A process may be performed to replace the first and second sacrificial layers SL1 and SL2 of the first and second mold structures ML1 and ML2 with first and second conductive patterns GE1 and GE2. Therefore, a stack structure ST may be formed on the second interlayer dielectric layer 150.

The replacement process for substituting the first and second conductive patterns GE1 and GE2 for the first and second sacrificial layers SL1 and SL2 may include isotropically etching the first and second sacrificial layers SL1 and SL2 by using an etch recipe having etch selectivity with respect to the first and second dielectric patterns ILD1 and ILD2, the vertical structures VS, and the second interlayer dielectric layer 150, depositing a conductive layer that fills empty spaces wherein the first and second sacrificial layers SL1 and SL2 are removed, and performing an isotropic etching process to divide the conductive layer into a plurality of conductive patterns.

According to some embodiments of the present inventive concepts, an upper conductive line 140 may be formed, and first and second trenches TR1 and TR2 may be formed to penetrate the upper conductive line 140. First and second gap-fill patterns GF1 and GF2 may be easily formed in the first and second trenches TR1 and TR2, and may be used as an etch stop layer when the first and second mold structures ML1 and ML2 are patterned. For example, the first and second gap-fill patterns GF1 and GF2 may prevent underlying structures from being etched during the procedure for etching the first and second mold structures ML1 and ML2 each having a large aspect ratio, and improved reliability may be achieved in semiconductor device fabrication. The first and second gap-fill patterns GF1 and GF2 may be removed subsequently, and the first and second trenches TR1 and TR2 may be used as a space where the preliminary vertical structure pVS is formed, with the result that a semiconductor device fabrication may be efficiently performed.

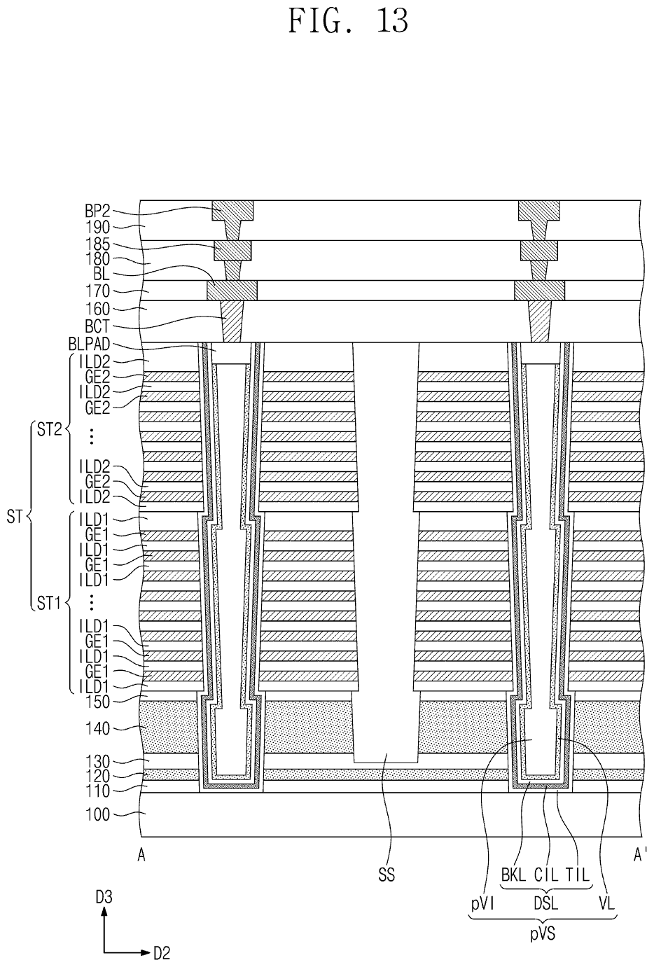

Referring to FIG. 13, a first lower dielectric layer 160 may be formed on the stack structure ST. Bit-line contact plugs BCT may be formed to penetrate the first lower dielectric layer 160 to come into coupling engagement with the vertical structures VS. The bit-line contact plugs BCT may be in contact with the bit-line conductive pads BLPAD of the vertical structures VS.

A second lower dielectric layer 170 may be formed on the first lower dielectric layer 160. Bit lines BL may be formed to penetrate the second lower dielectric layer 170. The bit lines BL may be electrically connected to the bit-line contact plugs BCT.

A third lower dielectric layer 180 may be formed on the second lower dielectric layer 170. Second lower conductive lines 185 may be formed to penetrate the third lower dielectric layer 180. The second lower conductive lines 185 may be connected to the bit line BL.

A fourth lower dielectric layer 190 may be formed on the third lower dielectric layer 180. A second bonding pad BP2 may be formed to penetrate the fourth lower dielectric layer 190.

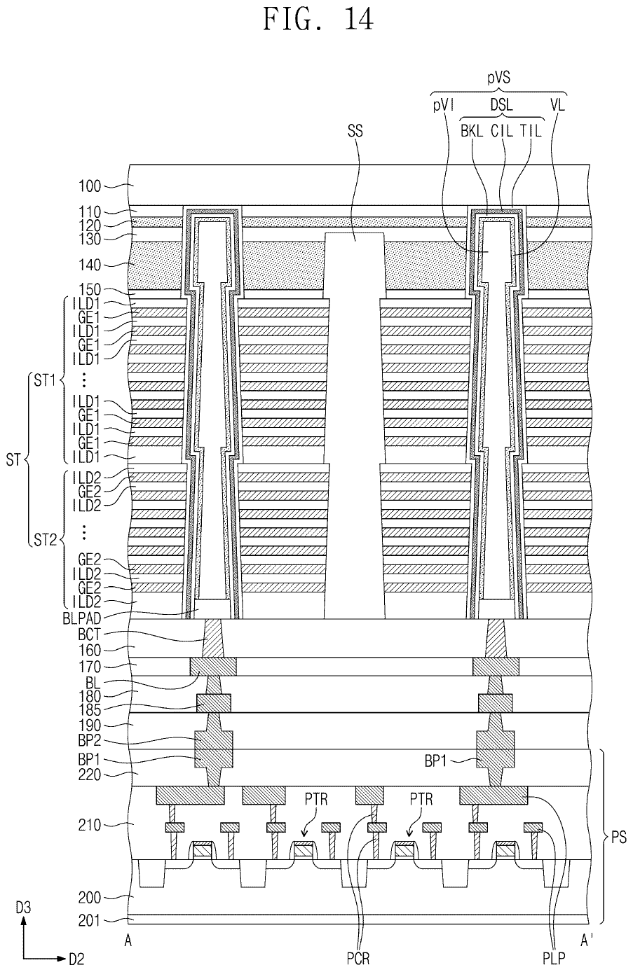

Referring to FIG. 14, a preliminary cell array structure of FIG. 13 may be bonded to the peripheral circuit structure PS formed on the substrate 200 of FIG. 8. Therefore, the first bonding pads BP1 of the peripheral circuit structure PS may be bonded to the second bonding pads BP2 of the preliminary cell array structure.

As the first bonding pads BP1 are bonded to the second bonding pads BP2, the preliminary cell array structure may be turned upside down. For example, the sub-substrate 100 of the preliminary cell array structure may be positioned at a top end.

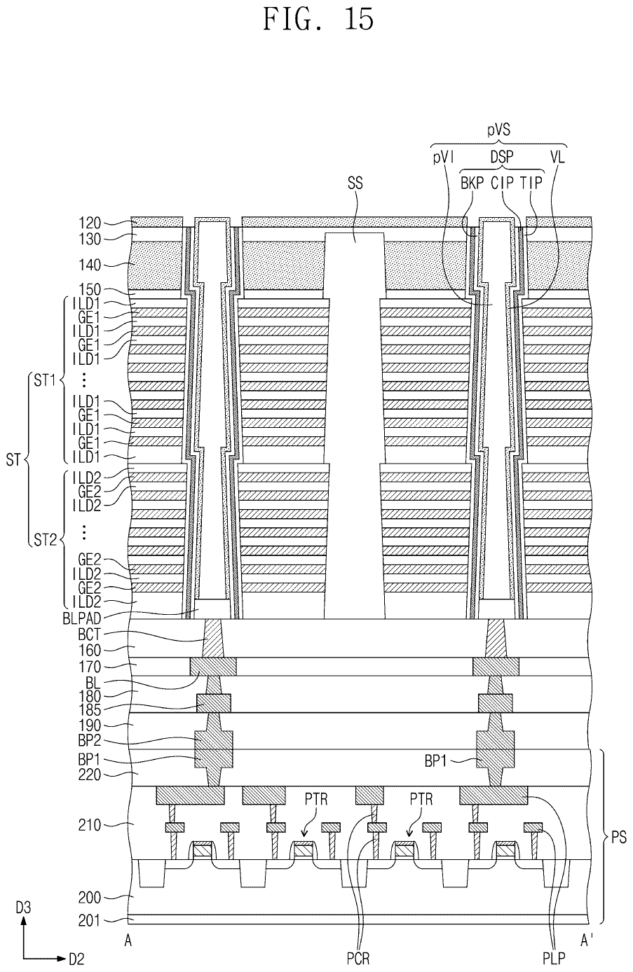

Referring to FIGS. 14 and 15, the sub-substrate 100 may be removed, and a top surface of the preliminary vertical structure pVS may be exposed. For example, the removal of the sub-substrate 100 may be achieved by at least one selected from a grinding process, a planarization process, a dry etching process, and a wet etching process. The term “exposed” (or “exposes,” or like terms) may be used herein to describe relationships between elements and/or with reference to intermediate processes in fabricating a semiconductor device, but may not require exposure of a particular element in the completed device. Likewise, the term “not exposed” may be used to described relationships between elements and/or with reference to intermediate processes in fabricating a semiconductor device, but may not require a particular element to be unexposed in the completed device.

An isotropic etching process may be performed on the preliminary interlayer dielectric layer 110 and an upper portion of the data storage layer DSL. The upper portion of the data storage layer DSL may be etched to form a data storage pattern DSP. In addition, an upper portion of the vertical channel layer VL may be exposed. The data storage pattern DSP may include a tunnel dielectric pattern TIP, a charge storage pattern CIP, and a blocking dielectric pattern BKP.

The isotropic etching process for the data storage layer DSL may use an etch recipe having selective etch selectivity with respect to the data storage layer DSL. The etching process for the data storage layer DSL may include isotropically etching the blocking dielectric layer BKL, the charge storage layer CIL, and the tunnel dielectric layer TIL.

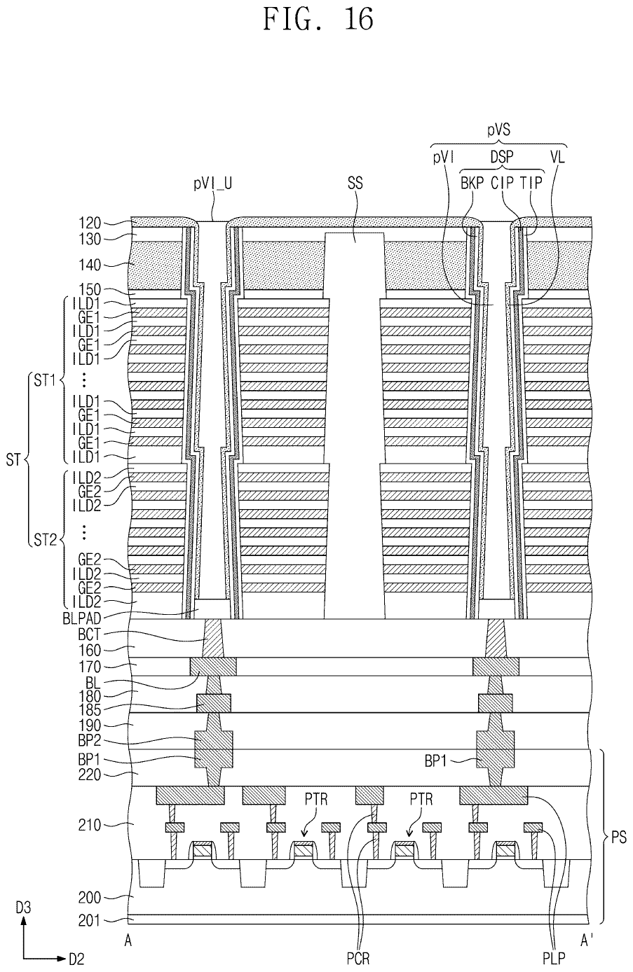

Referring to FIG. 16, a semiconductor material may be coated on the preliminary semiconductor layer 120 and the preliminary vertical structure pVS. The coating of the semiconductor material may allow the preliminary semiconductor layer 120 to connect with the preliminary vertical structure pVS. For example, the semiconductor material may include polysilicon.

An etch-back process may be performed on the preliminary semiconductor layer 120. The etch-back process may be executed to expose a top surface pVI_U of the preliminary vertical dielectric pattern pVI.

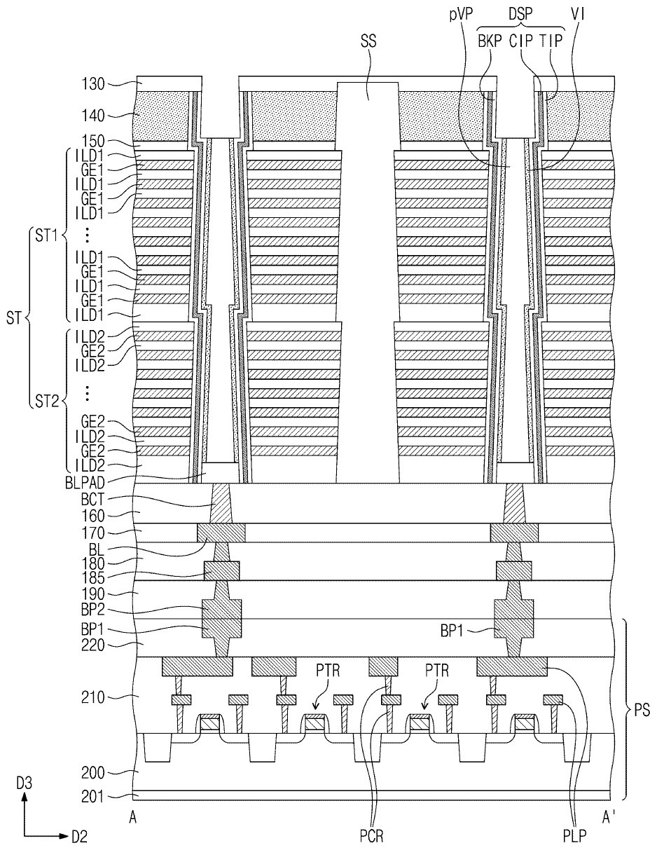

Referring to FIGS. 16 and 17, an upper portion of the preliminary vertical dielectric pattern pVI may be partially selectively removed. The removal of the upper portion of the preliminary vertical dielectric pattern pVI may form a vertical dielectric pattern VI.

The preliminary semiconductor layer 120 may be removed, and a portion of the vertical channel layer VL may be removed. The removal of the preliminary semiconductor layer 120 may expose a top surface of the first interlayer dielectric layer 130. The removal of a portion of the vertical channel layer VL may partially expose upper sidewalls of the data storage pattern DSP. The removal of a portion of the vertical channel layer VL may form a preliminary vertical channel pattern pVP. For example, a strip process may be employed to remove the preliminary semiconductor layer 120 and a portion of the vertical channel layer VL.

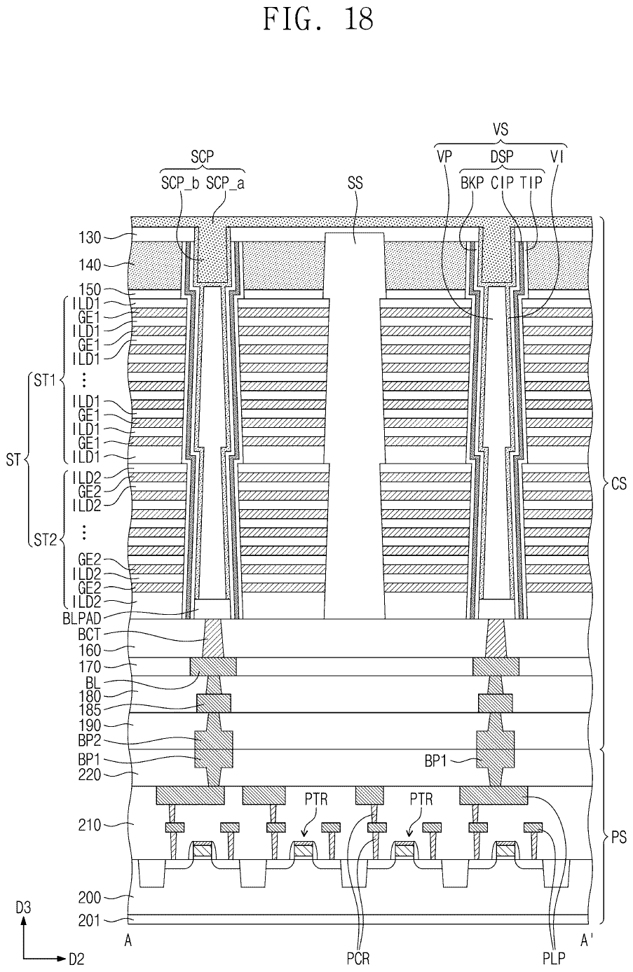

Referring to FIGS. 17 and 18, a vertical channel pattern VP and a source conductive pattern SCP may be formed. The vertical channel pattern VP may be formed by coating a semiconductor material on the preliminary vertical channel pattern pVP. The vertical channel pattern VP may extend to horizontally adjoin the first interlayer dielectric layer 130 and the upper conductive line 140. An inner wall of the vertical channel pattern VP may form a groove GR discussed with reference to FIG. 7. As the vertical channel pattern VP is formed, a vertical structure VS may be formed.

A source conductive pattern SCP may be formed to come into electrical connection with the vertical structure VS. The source conductive pattern SCP may include a first portion SCP_a on the first interlayer dielectric layer 130 and a second portion SCP_b that protrudes toward the vertical structure VS from the first portion SCP_a. The second portion SCP_b may fill a space in the vertical structure VS.

Referring back to FIG. 6A, an upper dielectric layer 310 may be formed on the source conductive pattern SCP. An upper via VA may be formed to penetrate the upper dielectric layer 310.

Wiring pads PAD may be formed on the upper dielectric layer 310. The wiring pads PAD may be electrically connected to the upper via VA. A capping dielectric layer 320 may be formed to cover the wiring pads PAD.

A semiconductor device according to some embodiments of the present inventive concepts may include an upper conductive line on a stack structure. The upper conductive line may be provided as a gate electrode of an erase transistor that induces a gate induced drain leakage (GIDL) on the stack structure, and a thickness of the upper conductive line may be greater than that of each of conductive patterns in the stack structure. For example, as the upper conductive line is formed thicker than the conductive patterns, it may be possible to increase efficiency of gate induced drain leakage and to improve reliability of the semiconductor device.

Furthermore, a gap-fill pattern adjacent to the upper conductive line may be formed during the formation of the upper conductive line. For the formation of the stack structure, the gap-fill pattern may be used as an etch stop layer for etching a mold structure having a large aspect ratio, and thus it may be possible to improve reliability in semiconductor device fabrication.

Although the present invention has been described in connection with some embodiments of the present inventive concepts illustrated in the accompanying drawings, it will be understood to those skilled in the art that various changes and modifications may be made without departing from the technical spirit and essential feature of the present inventive concepts. It will be apparent to those skilled in the art that various substitution, modifications, and changes may be thereto without departing from the scope and spirit of the present inventive concepts.

What is claimed is

1. A semiconductor device, comprising:
a substrate;
a stack structure comprising a plurality of dielectric patterns and a plurality of conductive patterns vertically and alternately stacked on the substrate;
a source conductive pattern on the stack structure;
an upper conductive line between the stack structure and the source conductive pattern; and
a plurality of vertical structures extending in a vertical direction perpendicular to a surface of the substrate through the stack structure and the upper conductive line and electrically connected to the source conductive pattern,
wherein a thickness of the upper conductive line in the vertical direction is greater than a thickness of each of the conductive patterns in the vertical direction,
wherein each of the plurality of vertical structures comprises:
a lower portion that extends through the stack structure; and
an upper portion that is connected to the lower portion and extends through the upper conductive line,
wherein a minimum width of the upper portion, in a horizontal direction parallel to the surface of the substrate, is greater than a minimum width, in the horizontal direction, of the lower portion.

2. The semiconductor device of claim 1, wherein the thickness of the upper conductive line in the vertical direction has a value of about 20 nm to about 1 μm.

3. The semiconductor device of claim 1, wherein each of the plurality of conductive patterns comprises a metallic material, and the upper conductive line comprises polysilicon.

4. The semiconductor device of claim 1, wherein the source conductive pattern comprises:
a first portion on the upper conductive line; and
a second portion connected to the first portion and extending through at least a portion of the upper conductive line,
wherein the second portion is connected to the plurality of vertical structures.

5. The semiconductor device of claim 4, wherein the second portion is horizontally adjacent to the upper conductive line.

6. The semiconductor device of claim 4, wherein
the second portion at least partially overlaps the plurality of vertical structures when viewed in plan view, and
the plurality of vertical structures extend around the second portion.

7. The semiconductor device of claim 4, wherein a top surface of an uppermost one of the plurality of conductive patterns is at a level lower than a level of a bottom surface of the second portion, relative to the surface of the substrate.

8. The semiconductor device of claim 1, wherein each of the plurality of vertical structures comprises:
a vertical dielectric pattern;
a vertical channel pattern that extends around a sidewall and a top surface of the vertical dielectric pattern; and
a data storage pattern that extends around a sidewall of the vertical channel pattern.

9. The semiconductor device of claim 8, wherein an uppermost end portion of the vertical channel pattern and an uppermost end portion of the data storage pattern are higher in the vertical direction than a top surface of the upper conductive line, relative to the surface of the substrate.

10. The semiconductor device of claim 8, wherein
the source conductive pattern comprises an impurity having a first conductivity type at a first concentration,
the vertical channel pattern comprises an impurity having the first conductivity type at a second concentration, and
the first concentration is greater than the second concentration.

11. The semiconductor device of claim 8, further comprising a plurality of horizontal dielectric patterns between the plurality of conductive patterns and the data storage pattern,
wherein the upper conductive line is in contact with the data storage pattern.

12. The semiconductor device of claim 11, wherein
each of the plurality of horizontal dielectric patterns comprises metal oxide containing a first metal, and
the upper conductive line does not contain the first metal.

13. The semiconductor device of claim 1, further comprising a separation structure that vertically extends through the stack structure,
wherein the separation structure extends through the upper conductive line.

14. A semiconductor device, comprising:
a peripheral circuit structure comprising a substrate, a plurality of peripheral circuits integrated on the substrate, and a plurality of first bonding pads electrically connected to the peripheral circuits; and
a cell array structure comprising a plurality of second bonding pads bonded to the first bonding pads,
wherein the cell array structure comprises:
a stack structure comprising a plurality of dielectric patterns and a plurality of conductive patterns that are vertically and alternately stacked;
a source conductive pattern on the stack structure;
an upper conductive line between the stack structure and the source conductive pattern;
a plurality of vertical structures that extend through the stack structure and the upper conductive line and are electrically connected to the source conductive pattern;
a plurality of bit lines that extend across the stack structure and are electrically connected to the vertical structures;
a first interlayer dielectric layer between the upper conductive line and the source conductive pattern; and
a second interlayer dielectric layer between the upper conductive line and the stack structure,
wherein a thickness of the upper conductive line in a vertical direction perpendicular to a surface of the substrate is greater than a thickness in the vertical direction of each of the plurality of conductive patterns,
wherein each of the plurality of vertical structures comprises:
a lower portion that extends through the stack structure; and
an upper portion that is connected to the lower portion and extends through the upper conductive line,
wherein a minimum width of the upper portion, in a horizontal direction parallel to the surface of the substrate, is greater than a minimum width, in the horizontal direction, of the lower portion, and
wherein the upper conductive line is provided as a gate electrode of an erase control transistor configured to induce a gate induced drain leakage (GIDL).

15. The semiconductor device of claim 14, wherein each of the plurality of conductive patterns comprises a metallic material, and the upper conductive line comprises polysilicon.

16. The semiconductor device of claim 14, wherein the source conductive pattern comprises:
a first portion on the upper conductive line; and
a second portion that is connected to the first portion and extends through at least a portion of the upper conductive line,
wherein the second portion is connected to the plurality of vertical structures.

17. The semiconductor device of claim 14, wherein each of the plurality of vertical structures comprises:
a vertical dielectric pattern;
a vertical channel pattern that extends around a sidewall and a top surface of the vertical dielectric pattern; and
a data storage pattern that extends around a sidewall of the vertical channel pattern.

18. The semiconductor device of claim 17, further comprising a plurality of horizontal dielectric patterns between the plurality of conductive patterns and the data storage pattern,
wherein the upper conductive line is in contact with the data storage pattern.

19. An electronic system, comprising:
a semiconductor device comprising a substrate and a cell array structure on the substrate; and
a controller electrically connected through an input/output pad to the semiconductor device, the controller controlling the semiconductor device,
wherein the cell array structure comprises:
a stack structure comprising a plurality of dielectric patterns and a plurality of conductive patterns that are vertically and alternately stacked on the substrate;
a plurality of vertical structures extending through the stack structure;
a source conductive pattern electrically connected to the plurality of vertical structures on the stack structure; and
an upper conductive line between the stack structure and the source conductive pattern,
wherein a thickness of the upper conductive line, in a vertical direction perpendicular to a surface of the substrate, is greater than a thickness, in the vertical direction, of each of the plurality of conductive patterns,
wherein each of the plurality of vertical structures comprises:
a lower portion that extends through the stack structure; and
an upper portion that is connected to the lower portion and extends through the upper conductive line,
wherein a minimum width of the upper portion, in a horizontal direction parallel to the surface of the substrate, is greater than a minimum width, in the horizontal direction, of the lower portion.

20. The electronic system of claim 19, wherein the cell array structure further comprises:
a plurality of bit lines extending across the stack structure and electrically connected to the plurality of vertical structures;
a first interlayer dielectric layer between the upper conductive line and the source conductive pattern; and
a second interlayer dielectric layer between the upper conductive line and the stack structure,
wherein the upper conductive line is a gate electrode of an erase control transistor configured to induce a gate induced drain leakage (GIDL).
